(19) United States
(12) Patent Application Publication
(10) Pub. No.: US 2025/0042349 A1
(43) Pub. Date: Feb. 6, 2025

(54) CENTRALIZED COMPUTING SYSTEM FOR A VEHICLE

(71) Applicant: Fisker Inc., Manhattan Beach, CA (US)

(72) Inventor: Shyam Sundar, Manhattan Beach, CA (US)

(21) Appl. No.: 18/792,915

(22) Filed: Aug. 2, 2024

Related U.S. Application Data
(60) Provisional application No. 63/517,251, filed on Aug. 2, 2023.

(51) Int. Cl. B60R 16/023; H01M 10/625; H05K 7/20

(52) U.S. Cl. CPC B60R 16/0238; B60R 16/0231; B60R 16/0239; H01M 10/625; H05K 7/20872; H01M 2220/20

(57) ABSTRACT

A centralized computing system for vehicle computing, comprising a first node module comprising: a first circuit board configured to control a first function of a vehicle; and a first housing enclosing the first circuit board and coupled to at least one component of the first circuit board; and a second node module comprising: a second circuit board configured to control a second function of the vehicle; and a second housing enclosing the second circuit board and coupled to at least one component of the second circuit board.

### RELATED APPLICATIONS

This application is related to and claims priority to U.S. Provisional Patent Application 63/517,251, titled “CENTRALIZED COMPUTING SYSTEM FOR A VEHICLE,” filed Aug. 2, 2023, and which is hereby incorporated by reference in its entirety.

### TECHNICAL FIELD

The present disclosure relates to the field of vehicle computing systems, and more specifically, for centralized vehicle computing systems for automotive vehicles.

### BACKGROUND

Conventional high-performance computing systems in automotive vehicles are typically packaged individually and distributed at different locations inside the vehicle. Consequently, the computing systems are connected through network interfaces and visual data interfaces. These connections are done via long and heavy wire harnesses. Routing the wiring harness across disparate locations of the vehicle creates complexities in packaging the computing systems and the components the systems control. Additionally, the computing systems being distributed in numerous locations in the vehicle makes thermal management difficult because each system must be cooled individually and the heat from the system may affect nearby components. When maintenance and repair is required, a technician must individually diagnose multiple computing system leading to increased repair time.

The conventional approach to packaging high-performance computing systems in vehicles results in significant space, complexity, weight, thermal, and cost problems. Therefore, there is a need for a high-performance computing system which reduces the complexity of the wire harness, improves packaging serviceability, maintenance and repairability, thermal management of the computing systems, redundancy of critical functions, and reduces the weight and cost of the system.

### SUMMARY

One aspect of the present disclosure is directed to a centralized computing system for vehicle computing, comprising a first node module comprising: a first circuit board configured to control a first function of a vehicle; and a first housing enclosing the first circuit board and coupled to at least one component of the first circuit board; and a second node module comprising: a second circuit board configured to control a second function of the vehicle; and a second housing enclosing the second circuit board and coupled to at least one component of the second circuit board.

These and other objects, features and advantages of the present invention will become more apparent from the following description when taken in connection with the accompanying drawings.

### BRIEF DESCRIPTION OF THE DRAWINGS

FIGS. 1-3 are illustrations of an exemplary embodiment of a centralized computing system.

FIG. 4 is a schematic diagram of an exemplary embodiment of a centralized computing system.

### DETAILED DESCRIPTION

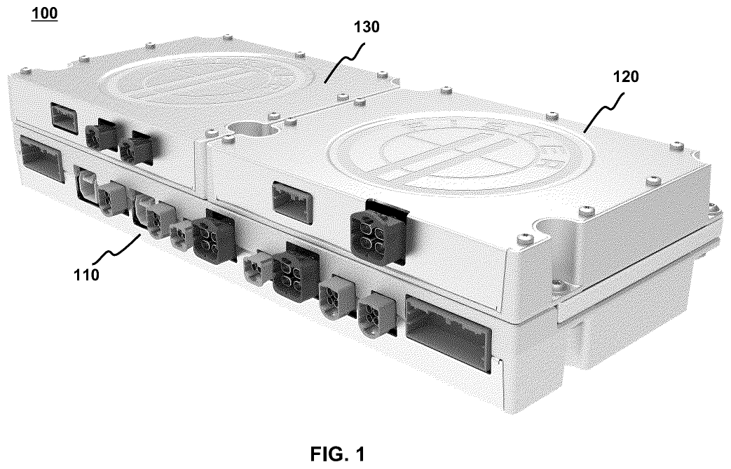

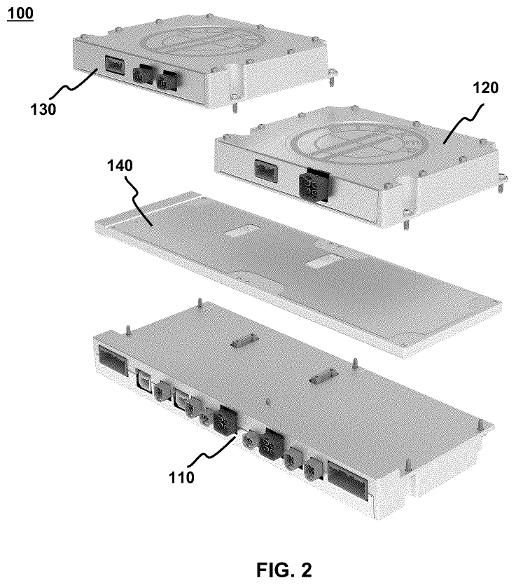

FIGS. 1-3 are exemplary illustrations of a centralized computing system 100 for a vehicle. The centralized computing system comprises a plurality of node modules 110, 120, 130. Each node module comprises a housing 111, 121, 131 with a cover 112, 122, 132 in which at least one circuit board 113, 123, 133 is mounted. The circuit board of each node module comprises at least one board to board (B2B) connector 124, 134 for connecting the circuit board of one node to another. The B2B connector 124, 134, 144 may comprise connections for multiple bus protocols. The housing 111, 121, 131 of each node module comprises an orifice corresponding to the respective B2B connector. The cover 112, 122, 132 of each node module may comprise a plurality of orifices for input and output (I/O) connectors.

The circuit board of each node module controls a different function of the vehicle. In the exemplary embodiment illustrated in FIGS. 1-3, the centralized computing system 100 comprises an Integrated Cockpit Compute (ICC) node module 110, an Integrated Virtualizer Compute (IVC) node module 120, and a Smart Communications Gateway (SCG) node module 130. In other embodiments the centralized computing system 100 may comprise additional node modules such as an Advanced Driver Assistance System (ADAS) node module (not shown). In other embodiments a node module may comprise two or more circuit boards controlling different functions of the vehicle. In some embodiments, a circuit board controlling a function of the vehicle may comprise a main circuit board and additional connected circuit boards, referred to as extension boards 115. The extension boards 115 may for example contain additional inputs and outputs or amplifiers. Separating the extension board 115 from main board can improve isolation and reduce electromagnetic interference (EMI). The centralized computing system reduces complexity by locating the computing nodes that control the various functions of the vehicle in a central location. The centralized location reduces wire harness complexity and improve communication speeds as the boards may directly communicate through a B2B connector 124, 134, 144. The centralized location further improves thermal management options by allowing the nodes to share a thermal regulation module 140. The centralized location reduces vehicle packaging restrictions to a single location.

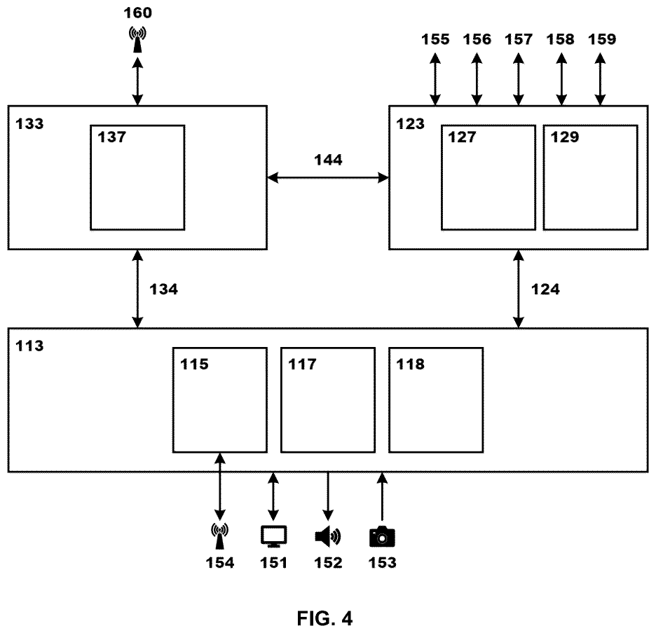

The ICC node module 110 controls vehicle functions including the infotainment and audio-visual systems. In an embodiment illustrated in FIG. 4, the ICC circuit board 113 comprises one or more System on a Chip (SOC) integrated circuit 117 and one or more microcontroller 118. The SOC 117 is an integrated circuit comprising at least a processor, memory, and connectivity. In other embodiments, the ICC circuit board 113 may comprise separate processors, memory, and connectivity circuits. The ICC circuit board 113 includes I/O connections to at least one cockpit display 151, audio speakers 152, and camera systems 153. In some embodiments the I/O connections may be provided on an extension board 115. In some embodiments the extension board 115 provides connections for wireless communication 154, such as Wi-Fi, Bluetooth, and radio broadcast.

The IVC node module 120 virtualizes Electronic Control Units (ECU) by creating software defined computers. In an embodiment illustrated in FIG. 4, the IVC circuit board 123 replaces traditional ECUs used around the vehicle to control various actuators. The IVC circuit board 123 comprises one or more SOC 127 and one or more network switch 128. In some embodiments, one or more additional SOC may be provided to provide redundant processing and improve safety. The IVC circuit board 123 may include I/O connections to network gateways 155, distributed nodes 156, legacy ECUs 157, vehicle sensors 158, and vehicle actuators 159. Compared to the conventional method of individual ECUs distributed throughout the vehicle, the IVC node module improves: the safety of vehicle by providing redundancy; improves performance by providing higher performance processing; reduces weight and cost by reducing the complexity of wiring harnesses; and improves maintenance and repair by centrally locating the computing system.

The SCG node module 130 controls communication in and out of the vehicle. In an embodiment illustrated in FIG. 4, the SCG circuit board 133 comprises one or more SOC 137 and, in some embodiments, may comprise one or more microcontrollers. The SOC 137 may provide connectivity for wireless communication 160 such as cellular, Wi-Fi or Bluetooth communication. The SCG circuit board 133 may include I/O connections for wireless communication.

In some embodiments the node modules may be connected to a thermal regulation module 140. The thermal regulation module 140 regulates the temperature of the node modules by transferring heat away from the node modules. The thermal regulation module comprises a heatsink 141 which is placed in thermal connection with the node modules. The node module housing 111, 121, 131 conducts heat away from the circuit board components, such as the SOC, either through direct contact or through a thermal pad or thermal compound. Heat is conducted from the node module housing 111, 121, 131 to the heatsink through direct contact or through a thermal pad, such as thermal pad 116. The heatsink may comprise one or more channels 143 for a heat transfer medium to conduct heat away from the centralized computing system. The channel 143 may be optimized for flow rate or to prioritize the cooling of particular components on the node module circuit boards. In some embodiment the heat transfer medium may be a liquid, such as water or coolant, and/or a gas, such as air. The heat transfer medium may be part of a cooling loop that extends outside of the centralized computing system. The cooling loop may be part of the vehicle cooling system that cools the vehicle engine, motor, or battery. The cooling loop may be part of the vehicle Heating, Ventilation, and Air Conditioning (HVAC) system. The cooling loop may be independent from the vehicle's cooling system. The cooling loop may be provided with an environment heat exchanger and a pump or fan for increasing the flow of the heat transfer medium. In embodiments with more than one heatsinks or channels, the coolant may flow through one or more loops that may be interconnected or independent. The thermal regulation module 140 may comprise one or more cover plates 142 on either side of the heatsink 141. The heatsink 141 and cover plate 143 may include orifices through which B2B connectors may pass.

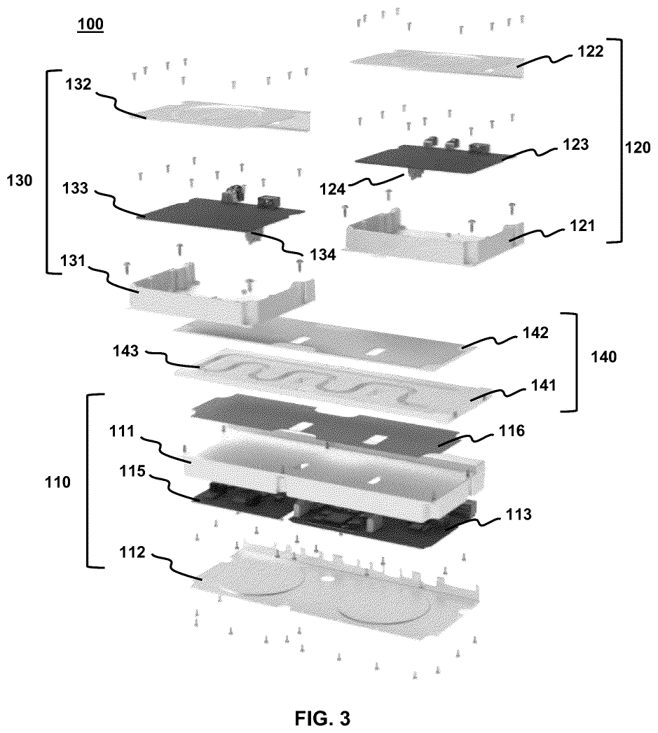

In an embodiment illustrated in FIG. 3, node modules 110, 120, 130 may be secured to the thermal regulation module 140 by fasteners such as screws or clips. In other embodiments two or more node modules may be secured to each other or a hub module. A hub module comprises a structure, such as a frame, for centrally securing node modules. Node modularity is achieved by configuring node modules to be individually removable and replaceable from the centralized computing system. Compared to conventional vehicle computing systems, the centralized computing system bode modularity improves versatility, repairability, maintenance, and upgradability of the system. Conventional vehicle computing systems require the entire computing system to be replaced or fully disassembled if a single board malfunctions. Node modularity allows for an individual module to be replaced if the node's circuit board malfunctions. A node module may be replaced with a higher performance node module. Node modularity also allows for different configuration of modules across a different vehicle models and configurations.

It will be apparent to those skilled in the art that various modifications and variations can be made to the disclosed vehicle structures. While illustrative embodiments have been described herein, the scope of the present disclosure includes any and all embodiments having equivalent elements, modifications, omissions, combinations (e.g., of aspects across various embodiments), adaptations and/or alterations as would be appreciated by those skilled in the art based on the present disclosure. The limitations in the claims are to be interpreted broadly based on the language employed in the claims and not limited to examples described in the present specification or during the prosecution of the application, which examples are to be construed as non-exclusive. It is intended, therefore, that the specification and examples be considered as exemplary only, with a true scope and spirit of the present disclosure being indicated by the following claims and their full scope of equivalents.

What is claimed is:

1. A centralized computing system for vehicle computing, comprising:
a first node module comprising:
a first circuit board configured to control a first function of a vehicle; and
a first housing enclosing the first circuit board and coupled to at least one component of the first circuit board; and
a second node module comprising:
a second circuit board configured to control a second function of the vehicle; and
a second housing enclosing the second circuit board and coupled to at least one component of the second circuit board.

2. The centralized computing system according to claim 1, wherein the first function and second function are different functions.

3. The centralized computing system according to claim 2, wherein one of the first and second functions is infotainment.

4. The centralized computing system according to claim 2, wherein one of the first and second functions is virtualized controllers.

5. The centralized computing system according to claim 2, wherein one of the first and second functions is wireless communication.

6. The centralized computing system according to claim 2, wherein one of the first and second functions is driver assistance.

7. The centralized computing system according to claim 1, wherein the first function is infotainment, and wherein the first circuit board comprises at least one system on a chip, the system on a chip configured to connect to at least one of a display, a speaker, and a camera.

8. The centralized computing system according to claim 1, wherein the second function is virtualized controllers, and wherein the second circuit board comprises at least one system on a chip and a network gateway, the network gateway configured to connect to at least one of a network gateway, a vehicle electronic control unit, and a vehicle actuator.

9. The centralized computing system according to claim 1, further comprising a third node module comprising:
a third circuit board configured to control a third function of a vehicle; and
a third housing enclosing the third circuit board and coupled to at least one component of the third circuit board.

10. The centralized computing system according to claim 9, further comprising a fourth node module comprising:
a fourth circuit board configured to control a fourth function of a vehicle; and
a fourth housing enclosing the third circuit board and coupled to at least one component of the fourth circuit board.

11. The centralized computing system according to claim 1, further comprising a thermal regulation module coupled to the first and second node modules for transferring heat from the first and second housings.

12. The centralized computing system according to claim 11, wherein the thermal regulation module comprises a heatsink, the heatsink comprising a channel for a heat transfer medium.

13. The centralized computing system according to claim 12, wherein the heat transfer medium is a liquid or a gas and the channel is connected to a vehicle cooling loop.

14. The centralized computing system according to claim 13, wherein the vehicle cooling loop also cools a vehicle battery.

15. The centralized computing system according to claim 1, wherein the first circuit board comprises a board-to-board connector configured to directly connect to the second circuit board.
